(19) United States
(12) Patent Application Publication
(10) Pub. No.: US 2019/0363154 A1
(43) Pub. Date: Nov. 28, 2019

(54) FLEXIBLE DISPLAY DEVICE AND METHOD OF MANUFACTURING FLEXIBLE DISPLAY DEVICE

(71) Applicant: Sharp Kabushiki Kaisha, Sakai City, Osaka (JP)

(72) Inventors: Seiji KANEKO, Sakai City (JP); Yohsuke KANZAKI, Sakai City (JP); Takao SAITOH, Sakai City (JP); Masaki YAMANAKA, Sakai City (JP); Masahiko MIWA, Sakai City (JP)

(21) Appl. No.: 16/467,068

(22) PCT Filed: Aug. 10, 2017
(86) PCT No.: PCT/JP2017/029077

§ 371 Date: Jun. 6, 2019

(51) Int. Cl. H01L 27/32; H01L 51/52; H01L 51/56; H01L 51/00

(52) U.S. Cl. CPC H01L 27/3276; H01L 51/0097; H01L 51/56; H01L 51/5253

(57) ABSTRACT

A photosensitive PI layer fills a bending region and is formed on a third insulating layer in a display region and a terminal region. An opening is formed in the photosensitive PI layer while exposing a gate electrode extension wiring line. A contact hole is formed in a second insulating layer and the third insulating layer.

### TECHNICAL FIELD

The disclosure relates to a flexible display device (flexible display device) and a method of manufacturing a flexible display device.

### BACKGROUND ART

Flexible display devices including flexible substrates (flexible substrates) have recently received considerable attention because the display devices can be bent freely.

In the field of such a flexible display device, similar to other display devices, frame narrowing is strongly required.

PTL 1 discloses a flexible display device in which a frame part including a pad is bent 180 degrees so as to be disposed at the back of a display surface in a display region, thereby reducing a frame part visible from the display surface side.

### CITATION LIST

### Patent Literature

PTL 1: JP 2014-232300 A (published on Dec. 11, 2014)

### SUMMARY

### Technical Problem

FIG. 10 is a diagram illustrating a schematic configuration of a frame part of a flexible display device in the related art disclosed in PTL 1.

The flexible display device in the related art disclosed in PTL 1 has such a configuration that a frame part including a pad PD can be bent 180 degrees in a bending region BA.

In a region including a bending region BA on a flexible substrate 101, an anti-etching layer 106 is provided, and a buffer film 102 being an inorganic film and a gate insulation film 103 being an inorganic film are formed that cover the anti-etching layer 106. On the gate insulation film 103, a gate wiring line GL is formed that has a predetermined shape, and an interlayer insulation film 104 being an inorganic film is formed that covers the gate wiring line GL.

As illustrated in the drawing, in the bending region BA on the flexible substrate 101, a bending hole BH penetrating the buffer film 102, the gate insulation film 103, and the interlayer insulation film 104 is formed in these three films with only the anti-etching layer 106 left as it is, to enable bending 180 degrees in the bending region BA. A lead wiring line hole LKH is formed in a portion, overlapping with the gate wiring line GL in a plan view, of the interlayer insulation film 104.

On the interlayer insulation film 104, a lead wiring line LK is formed that electrically connects the pad PD with the gate wiring line GL. In the bending region BA, the lead wiring line LK is formed that comes into contact with tapered portions TP1 and TP2 of the bending hole BH and the anti-etching layer 106.

A protective film 105 is formed that covers the lead wiring line LK. The lead wiring line LK is electrically connected with the gate wiring line GL via the lead wiring line hole LKH formed in the interlayer insulation film 104 and electrically connected with the pad PD via a pad hole PDH formed in the protective film 105.

Unfortunately, the flexible display device in the related art disclosed in PTL 1 has the following problems due to the structure of the bending region BA.

As illustrated in FIG. 10, the lead wiring line LK is formed that comes into contact with the tapered portions TP1 and TP2 of the bending hole BH and the anti-etching layer 106 in the bending region BA. To form the lead wiring line LK in this way without disconnection, the tapered portions TP1 and TP2 of the bending hole BH are required to be shaped into relatively gentle slopes.

If the tapered portions TP1 and TP2 of the bending hole BH are shaped into relatively gentle slopes as described above, the tapered portions TP1 and TP2 of the buffer film 102, the gate insulation film 103, and the interlayer insulation film 104 being inorganic films remain in the bending region BA. With wide variations in bending alignment in bending, a crack may readily occur in these portions, resulting in a problem that a crack occurring in the tapered portions TP1 and TP2 disconnects the lead wiring line LK.

There is also a problem that the lead wiring line LK formed along the tapered portions TP1 and TP2 of the bending hole BH shaped into relatively gentle slopes has an unnecessarily long length, resulting in an increase in resistance.

In light of the foregoing, an object of the disclosure is to provide a flexible display device in which a display region and a terminal region can be leveled, disconnection of a lead wiring line is suppressed in a bending region (bending region), and an increase in resistance due to the lead wiring line having an unnecessarily long length is suppressed; and a method of manufacturing the flexible display device.

### Solution to Problem

To solve the above problems, a flexible display device of the disclosure includes: a flexible substrate; and an active element and a display element disposed on the flexible substrate. The active element and the display element are disposed in a display region. A bending region and a terminal region are disposed in a vicinity of the display region, the bending region being adjacent to the display region, the terminal region being outside the bending region. One or more layers of inorganic films are disposed in each of the display region, the bending region, and the terminal region on the flexible substrate, and the one or more layers of inorganic films are at least partially removed in the bending region. A first resin layer fills the bending region and is formed on the one or more layers of inorganic films in the display region and the terminal region. A first opening is formed in the first resin layer and the one or more layers of inorganic films in the display region while exposing an extension wiring line electrically connected with the active element. A lead wiring line is electrically connected with the extension wiring line via the first opening and is formed on the first resin layer in the bending region.

With the above configuration, the first resin layer fills the bending region and is formed on the one or more layers of inorganic films in the display region and the terminal region. In addition, the lead wiring line is electrically connected with the extension wiring line via the first opening and is formed on the first resin layer in the bending region.

Thus, with the first resin layer, the display region and the terminal region can be leveled. In addition, disconnection of the lead wiring line can be suppressed in the bending region, and an increase in resistance due to the lead wiring line having an unnecessarily long length can be suppressed.

To solve the above problems, a method of manufacturing a flexible display device of the disclosure, the flexible display device including a display region, a bending region, and a terminal region, the display region being provided with an active element and a display element, the bending region being adjacent to the display region, the terminal region being outside the bending region, includes: forming the bending region by at least partially removing one or more layers of inorganic films formed in each of the display region, the bending region, and the terminal region; forming a first resin layer on the one or more layers of inorganic films in the display region and the terminal region, the first resin layer filling the bending region; forming a first opening in the first resin layer and the one or more layers of inorganic films in the display region, the first opening exposing an extension wiring line electrically connected with the active element; and forming a lead wiring line on the first resin layer in the bending region, the lead wiring line being electrically connected with the extension wiring line via the first opening.

With the above method, the first resin layer fills the bending region and is formed on the one or more layers of inorganic films in the display region and the terminal region. In addition, the lead wiring line is electrically connected with the extension wiring line via the first opening and is formed on the first resin layer in the bending region.

Thus, with the first resin layer, the display region and the terminal region can be leveled. In addition, disconnection of the lead wiring line can be suppressed in the bending region, and an increase in resistance due to the lead wiring line having an unnecessarily long length can be suppressed.

### Advantageous Effects of Disclosure

According to one aspect of the disclosure, the display region and the terminal region can be leveled. In addition, a flexible display device in which disconnection of the lead wiring line is suppressed in the bending region (bending region), and an increase in resistance due to the lead wiring line having an unnecessarily long length is suppressed; and a method of manufacturing the flexible display device can be provided.

### BRIEF DESCRIPTION OF DRAWINGS

FIGS. 1A and 1B are diagrams illustrating a schematic configuration of a flexible organic EL display device including a bending region.

FIG. 2 is a diagram for describing steps for manufacturing the flexible organic EL display device illustrated in FIGS. 1A and 1B.

FIGS. 3A to 3J are diagrams illustrating a schematic configuration of a display region (AA) of the flexible organic EL display device illustrated in FIGS. 1A and 1B.

FIGS. 4A to 4F are diagrams illustrating a schematic configuration of the bending region (BA) of the flexible organic EL display device illustrated in FIGS. 1A and 1B.

FIGS. 5A to 5C are diagrams for describing a Laser Lift Off step (also referred to as LLO step) included in the steps for manufacturing the flexible organic EL display device illustrated in FIGS. 1A and 1B.

FIG. 6 is a diagram for describing steps for manufacturing a flexible organic EL display device according to a second embodiment.

FIGS. 7A to 7F are diagrams illustrating a schematic configuration of a bending region (BA) of the flexible organic EL display device illustrated in FIG. 6.

FIGS. 8A to 8F are diagrams illustrating a schematic configuration of a bending region (BA) of a flexible organic EL display device according to a third embodiment.

FIGS. 9A to 9F are diagrams illustrating a schematic configuration of a bending region (BA) of a flexible organic EL display device according to a fourth embodiment.

FIG. 10 is a diagram illustrating a schematic configuration of a frame portion of a flexible display device in the related art disclosed in PTL 1.

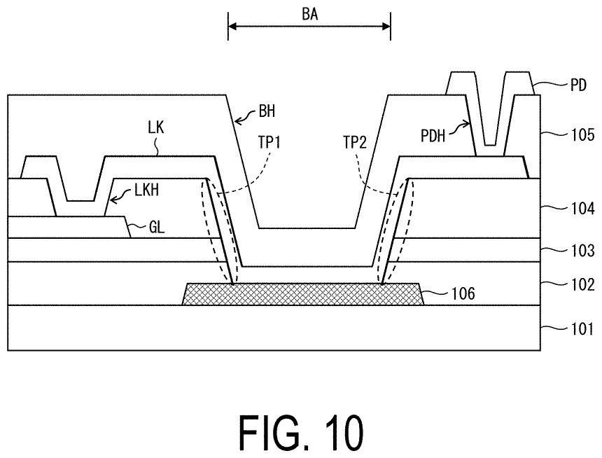

### DESCRIPTION OF EMBODIMENTS

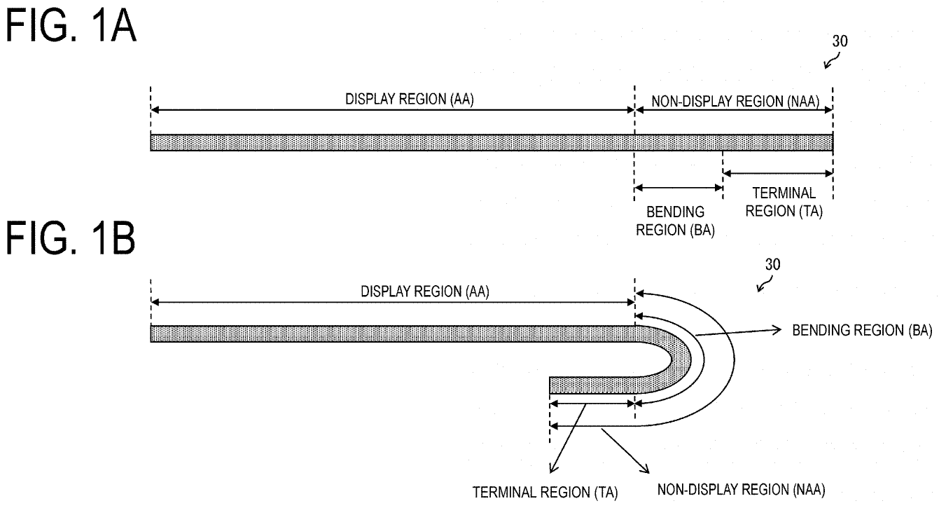

Embodiments of the disclosure will be described below with reference to FIG. 1A to FIG. 9F. Hereinafter, for the convenience of descriptions, a configuration having the same functions as those of a configuration described in a specific embodiment is denoted by the same reference numerals, and its descriptions may be omitted.

Note that each of the following embodiments is described as exemplifying an organic electro luminescence (EL) element as a display element (optical element). However, no such limitation is intended, and the display element may be, for example, a reflective liquid crystal display element whose luminance and transmittance are controlled by voltage and that requires no backlight.

The display element (optical element) may be an optical element whose luminance and transmittance are controlled by an electric current, and examples of the electric current-controlled optical element include an organic Electro Luminescence (EL) display provided with an Organic Light Emitting Diode (OLED), an EL display such as an inorganic EL display provided with an inorganic light emitting diode, or a Quantum Dot Light Emitting Diode (QLED) display provided with a QLED.

### First Embodiment

A first embodiment of the disclosure will be described with reference to FIG. 1A to FIG. 5C.

FIGS. 1A and 1B are diagrams illustrating a schematic configuration of a flexible organic EL display device 30 including a bending region BA.

FIG. 1A is a diagram illustrating a state in which the flexible organic EL display device 30 including the bending region BA is not bent, and FIG. 1B is a diagram illustrating a case in which the flexible organic EL display device 30 is bent in the bending region (BA) so that a terminal region (TA) is disposed at the back of a display surface in a display region (AA) and thus is not visible from the display surface side (the upper side in the drawing).

The present embodiment is described as exemplifying a case in which, as illustrated in FIG. 1A and FIG. 1B, a non-display region (NAA) is disposed in the right end region of the display region (AA) in the drawings and the upper end region (not illustrated) of the display region (AA). However, no such limitation is intended, and the non-display region (NAA) may be disposed in one or more of the right end region, the left end region, the upper end region, and the lower end region surrounding the display region (AA). For example, the non-display region (NAA) may be disposed in adjacent two regions or opposing two regions among these regions, or the non-display region (NAA) may be disposed in the four regions surrounding the display region (AA).

As illustrated in the drawings, the non-display region (NAA) of the flexible organic EL display device 30 includes the bending region (BA) and the terminal region (TA); and the bending region (BA) adjacent to the display region (AA) and the terminal region (TA) outside the bending region (BA) are disposed in the vicinity of the display region (AA).

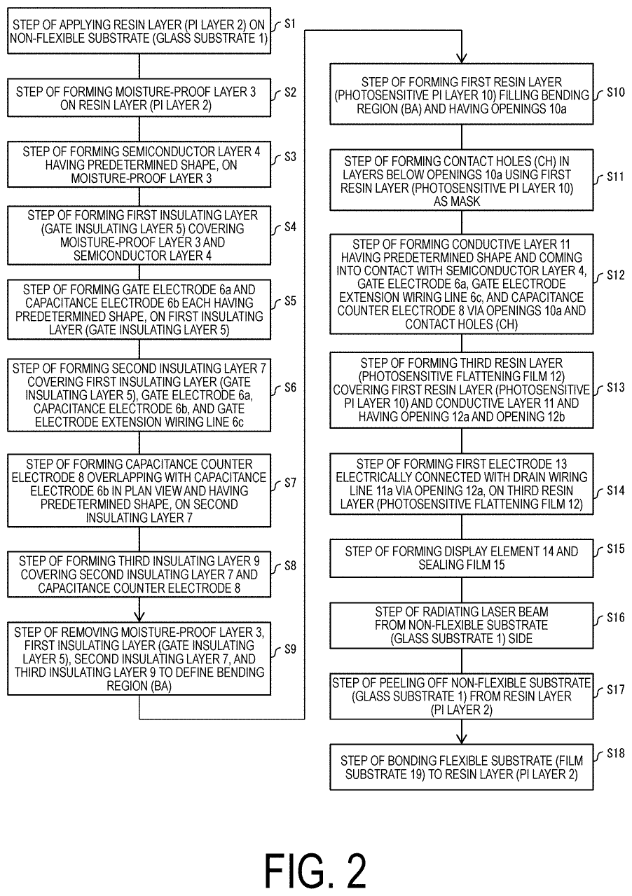

Steps for manufacturing the flexible organic EL display device 30 and schematic configurations of the display region (AA), the bending region (BA), and the terminal region (TA) of the flexible organic EL display device 30 will be described below with reference to FIG. 2 to FIG. 5C.

FIG. 2 is a diagram for describing steps for manufacturing the flexible organic EL display device 30.

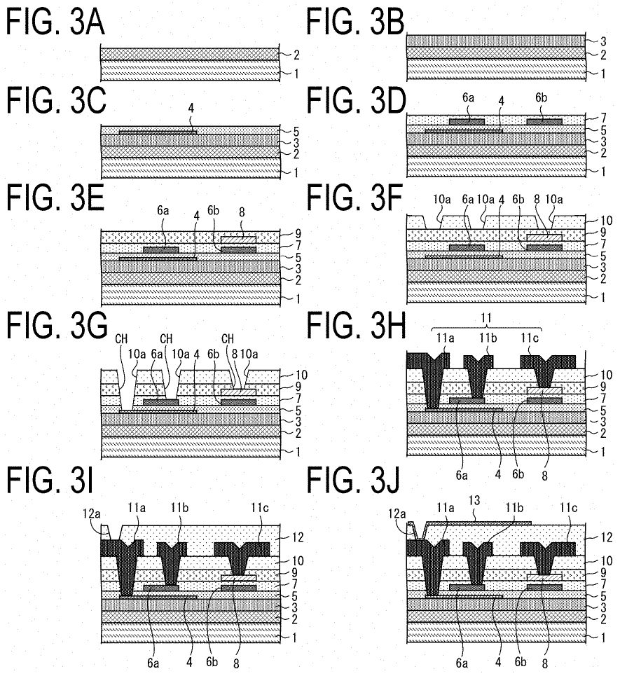

FIGS. 3A to 3J are diagrams illustrating a schematic configuration of the display region (AA) of the flexible organic EL display device 30.

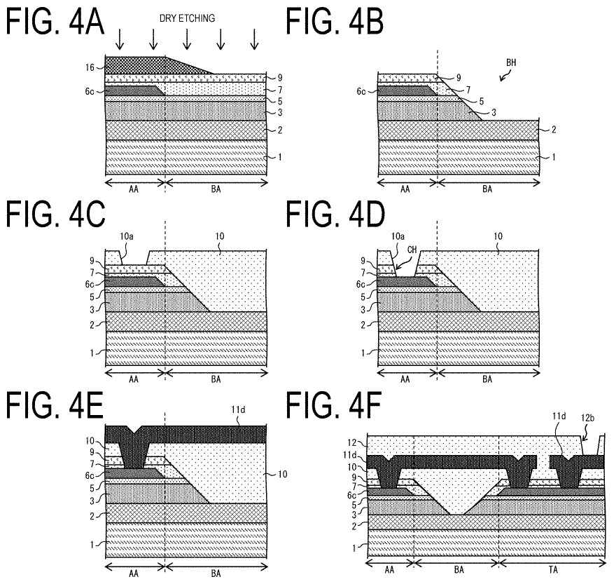

FIGS. 4A to 4F are diagrams illustrating a schematic configuration of the bending region (BA) of the flexible organic EL display device 30.

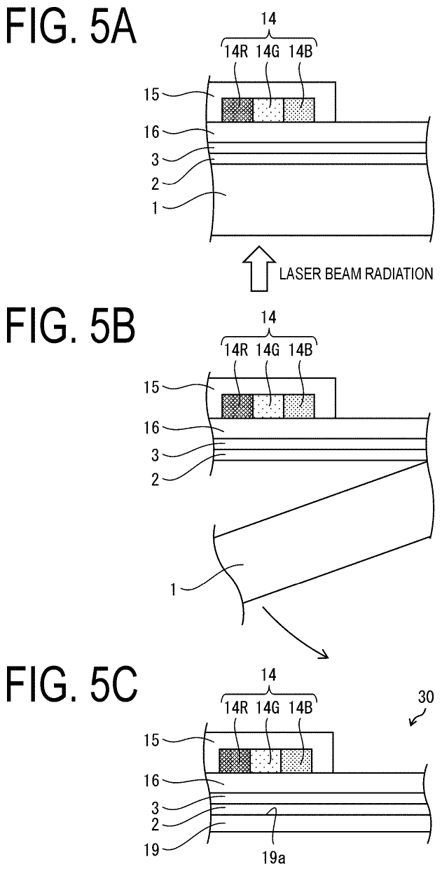

FIGS. 5A to 5C are diagrams for describing a Laser Lift Off step (also referred to as LLO step) included in the steps for manufacturing the flexible organic EL display device 30.

First, as illustrated in FIG. 2 and FIG. 3A, a PI layer 2 being a resin layer is applied on a glass substrate 1 being a non-flexible substrate (step S1).

The present embodiment is described as exemplifying a case of using the glass substrate 1 having a high heat resistance in consideration of a high temperature step included in the subsequent steps and transmission of a laser beam in a subsequent step. However, the substrate is not limited to a glass substrate as long as it can withstand the high temperature step included in the subsequent steps and can transmit a laser beam in the subsequent step.

Note that the PI layer 2 (a polyimide resin layer (second resin layer)) is used as the resin layer, and a laser beam is radiated from the glass substrate 1 side in the subsequent step to cause ablation at the interface between the PI layer 2 and the glass substrate 1, thereby enabling the glass substrate 1 to be peeled off from the PI layer 2.

Next, as illustrated in FIG. 2 and FIG. 3B, a moisture-proof layer 3 (also referred to as a barrier layer) is formed on the resin layer (PI layer 2) (step S2).

The moisture-proof layer is a layer that inhibits moisture or impurities from reaching an active element or a display element when the flexible organic EL display device 30 is being used, and the moisture-proof layer can be composed of, for example, a silicon oxide film, a silicon nitride film, a silicon oxynitride film, or a layered film thereof formed by CVD.

Next, as illustrated in FIG. 2 and FIG. 3C, a semiconductor layer 4 having a predetermined shape is formed on the moisture-proof layer 3 (step S3).

Step S3 described above includes a step of forming an amorphous silicon layer (a-Si layer) having a predetermined shape on the moisture-proof layer 3, a step of crystallizing the amorphous silicon layer formed on the moisture-proof layer 3 with an excimer laser, a step of doping impurities such as boron into a predetermined region of the crystallized polycrystalline silicon layer, and the like.

Next, as illustrated in FIG. 2 and FIG. 3C, a gate insulating layer 5 is formed as a first insulating layer covering the moisture-proof layer 3 and the semiconductor layer 4 (step S4).

The gate insulating layer 5 can be composed of, for example, a silicon oxide (SiOx) film, a silicon nitride (SiNx) film, or a layered film thereof formed by CVD.

Next, as illustrated in FIG. 2 and FIG. 3D, a gate electrode 6a and a capacitance electrode 6b each having a predetermined shape are formed on the gate insulating layer 5 (step S5), and thereafter, a second insulating layer 7 is formed that covers the gate insulating layer 5, the gate electrode 6a, the capacitance electrode 6b, and a gate electrode extension wiring line 6c (illustrated in FIGS. 4A to 4F) (step S6).

The second insulating layer 7 is an insulating film layer for forming a capacitor (capacitance element) and may be, for example, a silicon nitride (SiNx) film formed by CVD.

Next, as illustrated in FIG. 2 and FIG. 3E, a capacitance counter electrode 8 overlapping with the capacitance electrode 6b in a plan view and having a predetermined shape is formed on the second insulating layer 7 (step S7), and thereafter, a third insulating layer 9 is formed that covers the second insulating layer 7 and the capacitance counter electrode 8 (step S8).

The third insulating layer 9 can be composed of, for example, a silicon oxide (SiOx) film, a silicon nitride (SiNx) film, or a layered film thereof formed by CVD.

Next, as illustrated in FIG. 2, FIG. 4A, and FIG. 4B, the moisture-proof layer 3, the gate insulating layer 5, the second insulating layer 7, and the third insulating layer 9 are removed to form a bending hole (BH), thereby defining the bending region (BA) (step S9).

Note that, in the step of forming the bending hole (BH) by removing the moisture-proof layer 3, the gate insulating layer 5, the second insulating layer 7, and the third insulating layer 9, a resist film 16 including an inclined end portion (tapered end portion) is used as a mask, and dry etching is performed to form the bending hole (BH) as illustrated in FIG. 4A.

As illustrated in FIG. 4B, the bending hole (BH) thus formed has a shape having an inclined end portion (tapered end portion). The moisture-proof layer 3, the gate insulating layer 5, the second insulating layer 7, and the third insulating layer 9 are removed in one portion, that is, a central portion, of the bending region (BA), and remain in the vicinity of the boundary between the bending region (BA) and the display region (AA) and in the vicinity of the boundary between the bending region (BA) and the terminal region (TA).

The present embodiment is described as exemplifying a case in which the bending hole (BH) has the shape having the inclined end portion (tapered end portion). However, no such limitation is intended, and the bending hole (BH) may have a shape described in a third or fourth embodiment, which will be described later.

Note that, in consideration of bending 180 degrees and readiness of bending in the bending region (BA) of the flexible organic EL display device 30, the bending hole (BH) is preferably formed by removing all films of the layered film composed of the inorganic films but may be formed by removing only one or more films positioned in an upper part of the layered film composed of the inorganic films.

In addition, the present embodiment is described as exemplifying a case of forming the bending hole (BH) through dry etching; however, no such limitation is intended.

Next, as illustrated in FIG. 2, FIG. 3F, and FIG. 4C, a first resin layer (photosensitive PI layer 10) is formed that fills the bending region (BA) and has openings 10a (step S10).

Note that, in the present embodiment, the openings 10a of the photosensitive PI layer 10 are formed in the display region (AA) and the terminal region (TA).

The photosensitive PI layer 10 is formed from polyimide resin containing a photosensitive material and also functions as a flattening film eliminating the effect of difference in level of the lower layers.

Note that the photosensitive PI layer 10 may be positive-working or negative-working. In the present embodiment, a positive-working layer having the openings 10a formed in exposed portions is used.

In addition, in the present embodiment, the photosensitive PI layer 10 (polyimide resin containing a photosensitive material) is used in consideration of effectively inhibiting moisture or impurities from permeating. However, no such limitation is intended, and acrylic resin containing a photosensitive material or the like may be used.

In addition, the first resin layer may be formed from polyimide resin or acrylic resin containing no photosensitive material. In this case, the openings 10a can be formed through dry etching or the like using a resist film having a predetermined pattern and formed on the polyimide resin or acrylic resin containing no photosensitive material as a mask.

Next, as illustrated in FIG. 2, FIG. 3G, and FIG. 4D, contact holes (CH) are formed in layers below the openings 10a, using the photosensitive PI layer 10 as a mask (step S11).

As illustrated in FIG. 3G, a contact hole (CH) enabling contact with the semiconductor layer 4 is formed by removing the gate insulating layer 5, the second insulating layer 7, and the third insulating layer 9 being layers below the opening 10a, using the photosensitive PI layer 10 as a mask; a contact hole (CH) enabling contact with the gate electrode 6a is formed by removing the second insulating layer 7 and the third insulating layer 9 being layers below the opening 10a, using the photosensitive PI layer 10 as a mask; and a contact hole (CH) enabling contact with the capacitance counter electrode 8 is formed by removing the third insulating layer 9 being a layer below the opening 10a, using the photosensitive PI layer 10 as a mask.

Furthermore, as illustrated in FIG. 4D, a contact hole (CH) enabling contact with the gate electrode extension wiring line 6c is formed by removing the second insulating layer 7 and the third insulating layer 9 being layers below the opening 10a, using the photosensitive PI layer 10 as a mask.

As illustrated in FIG. 3G and FIG. 4D, the openings 10a formed in the photosensitive PI layer 10 overlap with the contact holes (CH) in a plan view.

In specific, in the present embodiment, the photosensitive PI layer 10 and the openings 10a formed in the photosensitive PI layer 10 are used as a mask for forming the contact holes (CH) so that the side surfaces of the contact holes (CH) are formed in such a manner as to extend from the side surfaces of the openings 10a formed in the photosensitive PI layer 10 and that the side surfaces of the openings 10a and the side surfaces of the contact holes (CH) are aligned with each other at portions of contact between the openings 10a and the contact holes (CH).

Note that all the contact holes (CH) illustrated in FIG. 3G and FIG. 4D may be formed in a single dry etching step because each of the gate electrode 6a, the capacitance counter electrode 8, and the gate electrode extension wiring line 6c functions as an etching stopper layer.

Next, as illustrated in FIG. 2, FIG. 3H, and FIG. 4E, a conductive layer 11 having a predetermined shape is formed that comes into contact with the semiconductor layer 4, the gate electrode 6a, the gate electrode extension wiring line 6c, and the capacitance counter electrode 8 via the openings 10a and the contact holes (CH) (step S12).

As illustrated in FIG. 3H, a drain wiring line 11a is formed that comes into contact with the semiconductor layer 4 via the opening 10a and the contact hole (CH) enabling contact with the semiconductor layer 4; a gate wiring line 11b is formed that comes into contact with the gate electrode 6a via the opening 10a and the contact hole (CH) enabling contact with the gate electrode 6a; and a capacitance wiring line 11c is formed that comes into contact with the capacitance counter electrode 8 via the opening 10a and the contact hole (CH) enabling contact with the capacitance counter electrode 8.

Furthermore, as illustrated in FIG. 4E, a lead wiring line 11d is formed that comes into contact with the gate electrode extension wiring line 6c via the opening 10a and the contact hole (CH) enabling contact with the gate electrode extension wiring line 6c.

The drain wiring line 11a, the gate wiring line 11b, the capacitance wiring line 112c, and the lead wiring line 11d can be formed in the step of forming the conductive layer 11.

Note that a source wiring line is omitted in FIGS. 3A to 3J, and the gate wiring line 11b is electrically connected with the source wiring line or the drain wiring line of another TFT element disposed in the display region (AA).

Next, as illustrated in FIG. 2, FIG. 31, and FIG. 4F, a third resin layer (photosensitive flattening layer 12) is formed that covers the photosensitive PI layer 10 and the conductive layer 11 and that has an opening 12a overlapping with the drain wiring line 11a in the conductive layer 11 in a plan view and an opening 12b overlapping with the lead wiring line 11d in the conductive layer 11 in a plan view (step S13).

Note that, similar to the case in the display region (AA) illustrated in FIG. 4E, the lead wiring line 11d is formed that comes into contact with the gate electrode extension wiring line 6c (conductive member) via the contact hole (CH) and the opening 10a also in the terminal region (TA) as illustrated in FIG. 4F.

In the vicinity of a terminal portion, the lead wiring line 11d is formed that comes into contact with the gate electrode extension wiring line 6c (conductive member) via the contact hole (CH) and the opening 10a; and a portion, exposed via the opening 12b of the photosensitive flattening layer 12, of the lead wiring line 11d functions as the terminal portion.

The present embodiment is described as exemplifying a case of using the configuration of the terminal portion illustrated in FIG. 4F; however, the configuration of the terminal portion is not limited to the illustrated configuration.

The photosensitive flattening layer 12 is a resin layer containing a photosensitive material and also functions as a flattening film eliminating the effect of difference in level of the lower layers. In the present embodiment, polyimide resin containing a photosensitive material is used as the photosensitive flattening layer 12 in consideration of more effectively inhibiting moisture or impurities from permeating; however, no such limitation is intended.

Note that the photosensitive flattening layer 12 may be of positive-working or negative-working. In the present embodiment, a positive-working layer having the openings 12a and 12b formed in exposed portions is used.

In addition, the third resin layer may be formed from polyimide resin or acrylic resin containing no photosensitive material. In this case, the openings 12a and 12b can be formed through dry etching or the like using a resist film having a predetermined pattern and formed on the polyimide resin or acrylic resin containing no photosensitive material as a mask.

As illustrated in FIG. 2 and FIG. 3J, a first electrode 13 (electrode layer) electrically connected with the drain wiring line 11a via the opening 12a is formed on the photosensitive flattening layer 12 (step S14).

As described above, in the flexible organic EL display device 30, the gate electrode extension wiring line 6c formed in the display region (AA) and the terminal region (TA) is electrically connected with the lead wiring line 11d formed in the display region (AA), the bending region (BA), and the terminal region (TA) and positioned on the photosensitive PI layer 10; and the gate electrode extension wiring line 6c and the lead wiring line 11d electrically connected with each other are electrically connected with a TFT element being an active element disposed in the display region (AA).

Note that the present embodiment is described as exemplifying a case in which the gate wiring line of the TFT element being the active element disposed in the display region (AA) is led to the terminal region (TA) via the gate electrode extension wiring line 6c and the lead wiring line 11d to form the terminal portion. However, no such limitation is intended, and similarly, the source wiring line of the TFT element being the active element disposed in the display region (AA) of the flexible organic EL display device 30 may also be led to another terminal region (TA) via an extension wiring line and a lead wiring line to form the terminal portion.

Next, as illustrated in FIG. 2 and FIG. 5A, a display element 14 and a sealing film 15 are formed (step S15).

Note that, in FIGS. 5A to 5C, a film including the semiconductor layer 4, the gate insulating layer 5, a layer where the gate electrode 6a and the like are formed, the second insulating layer 7, a layer where the capacitance counter electrode 8 is formed, the third insulating layer 9, the photosensitive PI layer 10, the conductive layer 11, and the photosensitive flattening layer 12 is referred to as layered film 16.

On the layered film 16, a plurality of red light emission organic EL elements 14R, a plurality of green light emission organic EL elements 14G, and a plurality of blue light emission organic EL elements 14B are formed, and the sealing film 15 is formed that covers the red light emission organic EL elements 14R, the green light emission organic EL elements 14G, and the blue light emission organic EL elements 14B.

Each of the red light emission organic EL elements 14R, the green light emission organic EL elements 14G, and the blue light emission organic EL elements 14B is composed of, for example, a layered body of the first electrode 13, a hole injection layer, a hole transport layer, a light-emitting layer for the corresponding color, an electron transport layer, an electron injection layer, and a second electrode, all of which are not illustrated.

Note that an edge cover is formed that surrounds each of the edges of the first electrode 13, which is not illustrated.

The sealing film 15 covers the red light emission organic EL elements 14R, the green light emission organic EL elements 14G, and the blue light emission organic EL elements 14B and inhibits foreign matter, such as water and oxygen, from permeating.

The sealing film 15 may include a first inorganic sealing film, an organic sealing film functioning as a buffer film formed above the first inorganic sealing film, and a second inorganic sealing film covering the first inorganic sealing film and the organic sealing film.

Each of the first inorganic sealing film and the second inorganic sealing film may be composed of, for example, a silicon oxide film, a silicon nitride film, a silicon oxynitride film, or a layered film thereof formed by CVD using a mask. The organic sealing film is a transparent organic insulating film that is thicker than the first inorganic sealing film and the second inorganic sealing film and may be formed from a coatable photosensitive organic material such as a polyimide or an acrylic. For example, after coating the first inorganic sealing film with an ink containing such an organic material using the inkjet method, the ink may be hardened by UV irradiation.

Note that the edge cover may be formed from a polyimide, an acrylic, or the like.

As illustrated in FIG. 2 and FIG. 5A, a laser beam is radiated from the side having the glass substrate 1 being a non-flexible substrate (step S16), and ablation is caused at the interface between the PI layer 2 and the glass substrate 1.

Then, as illustrated in FIG. 2 and FIG. 5B, the glass substrate 1 is peeled off from the PI layer 2 (step S17).

Lastly, as illustrated in FIG. 2 and FIG. 5C, a film substrate 19 being a flexible substrate is bonded to the PI layer 2 via an adhesive layer (not illustrated) provided on a surface 19a on one side of the film substrate 19, and the flexible organic EL display device 30 is completed (step S18).

As described above, according to the flexible organic EL display device 30, the photosensitive PI layer 10 fills the bending hole (BH) formed in the bending region (BA) and is formed in the display region (AA) and the terminal region (TA).

In the steps for manufacturing the flexible organic EL display device 30 described with reference to FIG. 2 to FIG. 5C, each of the contact holes (CH) is formed by removing, respectively, the second insulating layer 7 and the third insulating layer 9, and the gate insulating layer 5, being layers below the opening 10a, the second insulating layer 7 and the third insulating layer 9, and the third insulating layer 9, using the first resin layer (photosensitive PI layer 10) and the openings 10a formed in the first resin layer (photosensitive PI layer 10) as a mask.

The contact holes (CH) formed by removing the gate insulating layer 5, the second insulating layer 7, and the third insulating layer 9 as described above are deep. Thus, if first the contact holes (CH) are formed by removing the gate insulating layer 5, the second insulating layer 7, and the third insulating layer 9 and then the first resin layer (photosensitive PI layer 10) is formed on the layers, the first resin layer (photosensitive PI layer 10) or the resist film enters the deep contact holes (CH) and remains there, causing a problem that a fault readily occurs in the formation of the contact holes (CH).

In the steps for manufacturing the flexible organic EL display device 30 of the present embodiment, after the openings 10a are formed in the first resin layer (photosensitive PI layer 10), each of the contact holes (CH) is formed by removing, respectively, the second insulating layer 7 and the third insulating layer 9, and the gate insulating layer 5, being layers below the opening 10a, the second insulating layer 7 and the third insulating layer 9 and the third insulating layer 9, using the first resin layer (photosensitive PI layer 10) and the openings 10a formed in the first resin layer (photosensitive PI layer 10) as a mask. This can suppress the fault in the formation of the contact holes (CH).

Moreover, the first resin layer (photosensitive PI layer 10) is formed also in the display region (AA) so that the display region (AA) can be leveled to some extent, and the flexible organic EL display device 30 in which parasitic capacitance between the wiring lines is suppressed can be achieved.

Note that the present embodiment has been described as exemplifying the steps for manufacturing the flexible organic EL display device 30 including the Laser Lift Off step (LLO step). However, no such limitation is intended, and it should be understood that the disclosure can also be applied to steps for manufacturing the flexible organic EL display device including no Laser Lift Off step (LLO step).

Note that the present embodiment has been described as exemplifying a case in which the extension wiring line (conductive member) is the gate electrode extension wiring line 6c. However, no such limitation is intended, and the extension wiring line (conductive member) may be, for example, a capacitance wiring line. As long as the extension wiring line (conductive member) is in a conductive layer below the conductive layer 11, its type is not particularly limited.

### Second Embodiment

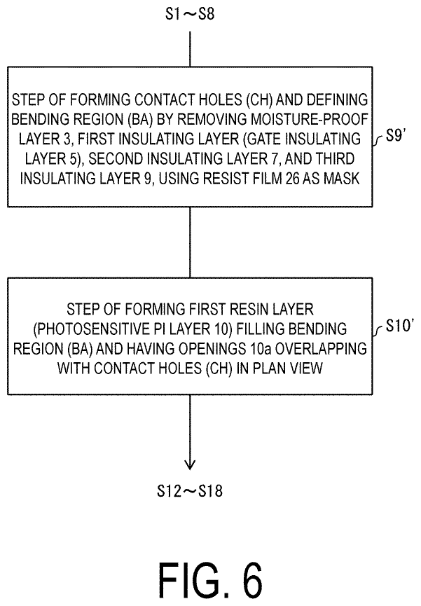

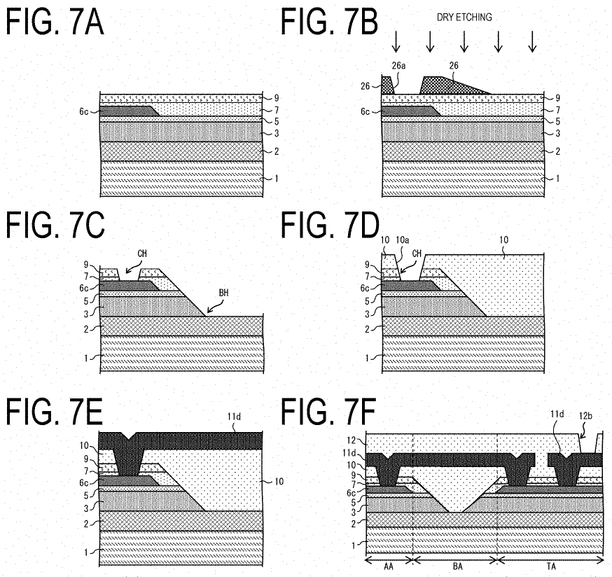

Next, a second embodiment of the disclosure will be described with reference to FIG. 6 and FIGS. 7A to 7F. The present embodiment differs from the first embodiment in that the contact holes (CH) and the bending hole (BH) are formed in a single step and that the contact holes (CH) are formed before the openings 10a are formed in the first resin layer (photosensitive PI layer 10). The other points are as described in the first embodiment. For the convenience of descriptions, members having the same functions as those of the members illustrated in the diagrams in the first embodiment are denoted by the same reference numerals, and descriptions thereof will be omitted.

FIG. 6 is a diagram for describing steps for manufacturing a flexible organic EL display device according to the present embodiment.

FIGS. 7A to 7F are diagrams illustrating a schematic configuration of a bending region (BA) of the flexible organic EL display device according to the present embodiment.

Through step S1 to step S8 illustrated in FIG. 2 and FIG. 6, the configuration illustrated in FIG. 7A can be obtained.

Thereafter, as illustrated in FIG. 7B, a resist film 26 having openings 26a in positions overlapping in a plan view with openings 10a and contact holes (CH) formed in a subsequent step is formed on the third insulating layer 9.

Then, as illustrated in FIG. 6 and FIG. 7C, using the resist film 26 and the openings 26a of the resist film 26 as a mask, the contact holes (CH) are formed, and at the same time the moisture-proof layer 3, the gate insulating layer 5, the second insulating layer 7, and the third insulating layer 9 are removed from a region where no resist film 26 is formed to form the bending hole (BH), thereby defining the bending region (BA) (step S9′).

Note that, in the present embodiment, the contact holes (CH) are formed in the display region (AA) and the terminal region (TA).

Thereafter, as illustrated in FIG. 6 and FIG. 7D, a first resin layer (photosensitive PI layer 10) is formed that fills the bending region (BA) and has the openings 10a overlapping with the contact holes (CH) in a plan view (step S10′).

Then, through step S12 to step S18 illustrated in FIG. 2 and FIG. 6, a flexible organic EL display device having the configuration illustrated in FIG. 7E and FIG. 7F can be achieved.

As described above, according to the flexible organic EL display device illustrated in FIG. 7F, the photosensitive PI layer 10 fills the bending hole (BH) formed in the bending region (BA) and is formed in the display region (AA) and the terminal region (TA).

In the manufacturing method of the present embodiment, as illustrated in FIG. 7C and FIG. 7D, the contact holes (CH) and the bending hole (BH) are formed in a single step, and the contact holes (CH) are formed before the openings 10a are formed in the first resin layer (photosensitive PI layer 10).

Thus, in consideration of a problem that the first resin layer (photosensitive PI layer 10) or the resist film entering the deep contact holes (CH) and remaining there readily causes a fault in the formation of the contact holes (CH), the first resin layer (photosensitive PI layer 10) is preferably a negative-working layer, in which an unexposed portion is removed, to enable the first resin layer (photosensitive PI layer 10) remaining in the contact holes (CH) to be readily removed, and the first resin layer (photosensitive PI layer 10) is preferably developed while the glass substrate 1 including the photosensitive PI layer 10 is thoroughly immersed in a developing solution or while the glass substrate 1 including the photosensitive PI layer 10 is turned over and thoroughly immersed in a developing solution.

### Third Embodiment

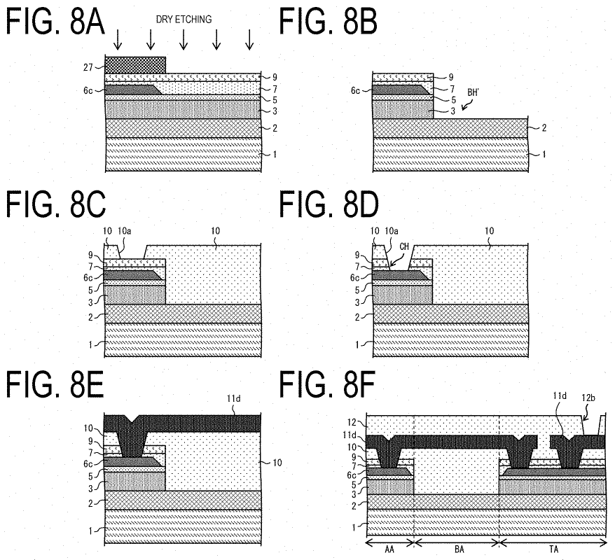

Next, a third embodiment of the disclosure will be described with reference to FIGS. 8A to 8F. The present embodiment differs from the first embodiment in that a bending hole (BH′) has a shape having no inclined end portion (tapered end portion) and that the bending region (BA) is an opening region where the moisture-proof layer 3, the gate insulating layer 5, the second insulating layer 7, and the third insulating layer 9 are removed. The other points are as described in the first embodiment. For the convenience of descriptions, members having the same functions as those of the members illustrated in the diagrams in the first embodiment are denoted by the same reference numerals, and descriptions thereof will be omitted.

FIGS. 8A to 8F are diagrams illustrating a schematic configuration of a bending region (BA) of a flexible organic EL display device according to the present embodiment.

As illustrated in FIG. 8A and FIG. 8B, using a resist film 27 as a mask, the moisture-proof layer 3, the gate insulating layer 5, the second insulating layer 7, and the third insulating layer 9 are removed from a region where no resist film 27 is formed to form a bending hole (BH′) having a shape having no inclined end portion (tapered end portion), thereby defining the bending region (BA).

As illustrated in FIG. 8F, the bending region (BA) is an opening region where the moisture-proof layer 3, the gate insulating layer 5, the second insulating layer 7, and the third insulating layer 9 are removed so that the moisture-proof layer 3, the gate insulating layer 5, the second insulating layer 7, and the third insulating layer 9 being inorganic films are not in the bending region (BA) of the flexible organic EL display device of the present embodiment. This configuration further improves readiness of bending in the bending region (BA) and prevents a crack or the like in the inorganic films.

As described above, according to the flexible organic EL display device illustrated in FIG. 8F, the photosensitive PI layer 10 fills the bending hole (BH) formed in the bending region (BA) and is formed in the display region (AA) and the terminal region (TA).

Note that descriptions of FIG. 8C, FIG. 8D, and FIG. 8E are as described in the first embodiment, except for the different shape of the bending hole (BH′), and are thus omitted.

### Fourth Embodiment

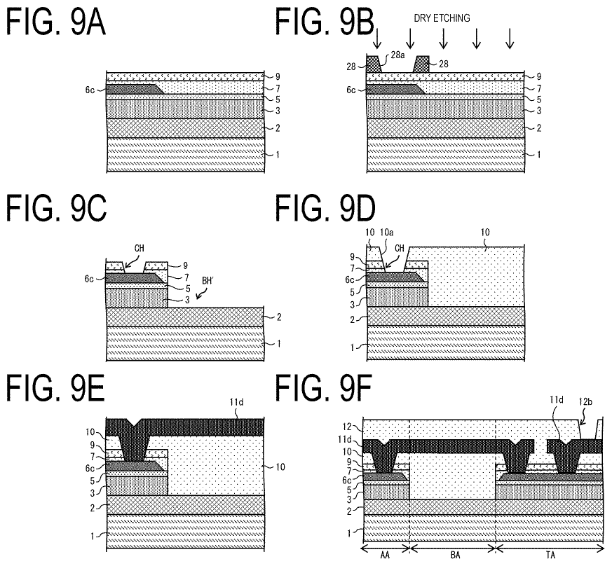

Next, a fourth embodiment of the disclosure will be described with reference to FIGS. 9A to 9F. The present embodiment differs from the second embodiment in that a bending hole (BH′) has a shape having no inclined end portion (tapered end portion) and that the bending region (BA) is an opening region where the moisture-proof layer 3, the gate insulating layer 5, the second insulating layer 7, and the third insulating layer 9 are removed. The other points are as described in the second embodiment. For the convenience of explanation, members having the same function as those illustrated in the drawings of the second embodiment are denoted using the same reference numerals, and descriptions thereof will be omitted.

FIGS. 9A to 9F are diagrams illustrating a schematic configuration of a bending region (BA) of a flexible organic EL display device according to the present embodiment.

As illustrated in FIG. 9B and FIG. 9C, using a resist film 28 and openings 28a of the resist film 28 as a mask, the contact holes (CH) are formed, and at the same time the moisture-proof layer 3, the gate insulating layer 5, the second insulating layer 7, and the third insulating layer 9 are removed from a region where no resist film 28 is formed to form a bending hole (BH′) having a shape having no inclined end portion (tapered end portion), thereby defining the bending region (BA).

As illustrated in FIG. 9F, the bending region (BA) is an opening region where the moisture-proof layer 3, the gate insulating layer 5, the second insulating layer 7, and the third insulating layer 9 are removed so that the moisture-proof layer 3, the gate insulating layer 5, the second insulating layer 7, and the third insulating layer 9 being inorganic films are not in the bending region (BA) of the flexible organic EL display device of the present embodiment. This configuration further improves readiness of bending in the bending region (BA) and prevents a crack or the like in the inorganic films.

As described above, according to the flexible organic EL display device illustrated in FIG. 9F, the photosensitive PI layer 10 fills the bending hole (BH) formed in the bending region (BA) and is formed in the display region (AA) and the terminal region (TA).

Note that descriptions of FIG. 9A, FIG. 9D, and FIG. 9E are as described in the second embodiment, except for the different shape of the bending hole (BH′), and are thus omitted.

### Supplement

According to aspect 1 of the disclosure, to solve the above problems, a flexible display device includes: a flexible substrate; and an active element and a display element disposed on the flexible substrate. The active element and the display element are disposed in a display region. A bending region and a terminal region are disposed in a vicinity of the display region, the bending region being adjacent to the display region, the terminal region being outside the bending region. One or more layers of inorganic films are disposed in each of the display region, the bending region, and the terminal region on the flexible substrate, and the one or more layers of inorganic films are at least partially removed in the bending region. A first resin layer fills the bending region and is formed on the one or more layers of inorganic films in the display region and the terminal region. A first opening is formed in the first resin layer and the one or more layers of inorganic films in the display region while exposing an extension wiring line electrically connected with the active element. A lead wiring line is electrically connected with the extension wiring line via the first opening and is formed on the first resin layer in the bending region.

With the above configuration, the first resin layer fills the bending region and is formed on the one or more layers of inorganic films in the display region and the terminal region. In addition, the lead wiring line is electrically connected with the extension wiring line via the first opening and is formed on the first resin layer in the bending region.

Thus, with the first resin layer, the display region and the terminal region can be leveled. In addition, disconnection of the lead wiring line can be suppressed in the bending region, and an increase in resistance due to the lead wiring line having an unnecessarily long length can be suppressed.

According to aspect 2 of the disclosure, in the flexible display device having the configuration of aspect 1, the first opening may include an opening formed in the first resin layer and an opening formed in the one or more layers of inorganic films, and side surfaces of the opening formed in the first resin layer and side surfaces of the opening formed in the one or more layers of inorganic films may be aligned with each other at portions of contact between the opening formed in the first resin layer and the opening formed in the one or more layers of inorganic films.

The above configuration can suppress a fault in formation of the first opening.

According to aspect 3 of the disclosure, in the flexible display device having the configuration of aspect 1 or 2, a second opening may be formed in the first resin layer and the one or more inorganic films in the display region while exposing a semiconductor layer or a gate electrode of the active element, and a wiring line for the active element may be electrically connected with the active element via the second opening.

The above configuration can achieve a flexible display device having the second opening in the display region.

According to aspect 4 of the disclosure, in the flexible display device having the configuration of aspect 3, the second opening may include an opening formed in the first resin layer and an opening formed in the one or more inorganic films, and side surfaces of the opening formed in the first resin layer and side surfaces of the opening formed in the one or more inorganic films may be aligned with each other at portions of contact between the opening formed in the first resin layer and the opening formed in the one or more inorganic films.

The above configuration can suppress a fault in formation of the second opening.

According to aspect 5 of the disclosure, in the flexible display device having the configuration of aspect 1 or 3, a capacitance element may be disposed in the display region, the capacitance element including a capacitance electrode and a capacitance counter electrode formed on a layer above the capacitance electrode via an insulating layer, a third opening may be formed in the first resin layer and the one or more layers of inorganic films in the display region while exposing the capacitance counter electrode, and a wiring line for the capacitance element may be electrically connected with the capacitance counter electrode via the third opening.

The above configuration can achieve a flexible display device having the third opening in the display region.

According to aspect 6 of the disclosure, in the flexible display device having the configuration of aspect 5, the third opening may include an opening formed in the first resin layer and an opening formed in the one or more inorganic films, and side surfaces of the opening formed in the first resin layer and side surfaces of the opening formed in the one or more inorganic films may be aligned with each other at portions of contact between the opening formed in the first resin layer and the opening formed in the one or more inorganic films.

The above configuration can suppress a fault in the formation of the third opening.

According to aspect 7 of the disclosure, in the flexible display device having the configuration of any one of aspects 1, 3, and 5, a fourth opening may be formed in the first resin layer and the one or more layers of inorganic films in the terminal region while exposing a conductive member, and the lead wiring line may be electrically connected with the conductive member via the fourth opening.

The above configuration can achieve a flexible display device having the fourth opening in the terminal region.

According to aspect 8 of the disclosure, in the flexible display device having the configuration of aspect 7, the fourth opening may include an opening formed in the first resin layer and an opening formed in the one or more layers of inorganic films, and side surfaces of the opening formed in the first resin layer and side surfaces of the opening formed in the one or more layers of inorganic films may be aligned with each other at portions of contact between the opening formed in the first resin layer and the opening formed in the one or more layers of inorganic films.

The above configuration can suppress a fault in formation of the fourth opening.

According to aspect 9 of the disclosure, in the flexible display device having the configuration of any one of aspects 1 to 8, the bending region may include an opening region of the one or more layers of inorganic films.

The above configuration can achieve a flexible display device in which readiness of bending in the bending region is further improved, and a crack or the like is prevented in the bending region.

According to aspect 10 of the disclosure, in the flexible display device having the configuration of any one of aspects 1 to 9, the first resin layer may be formed from polyimide resin containing a photosensitive material.

The above configuration can achieve a flexible display device in which the first resin layer can be patterned in exposure and development steps, and moisture or impurities can be more effectively inhibited from permeating.

According to aspect 11 of the disclosure, in the flexible display device having the configuration of any one of aspects 1 to 9, the first resin layer may be formed from acrylic resin containing a photosensitive material.

The above configuration can achieve a flexible display device in which the first resin layer can be patterned in exposure and development steps and, in a case of the display element of a bottom emission type, a decrease in transmittance of emitted light due to the first resin layer is reduced.

According to aspect 12 of the disclosure, in the flexible display device having the configuration of any one of aspects 1 to 11, the display element may include an organic EL display element.

The above configuration can achieve a flexible display device including an organic EL display element as the display element.

According to aspect 13 of the disclosure, in the flexible display device having the configuration of any one of aspects 1 to 11, the display element may include a reflective liquid crystal display element.

The above configuration can achieve a flexible display device including a reflective liquid crystal display element as the display element.

According to aspect 14 of the disclosure, to solve the above problems, a method of manufacturing a flexible display device including a display region, a bending region, and a terminal region, the display region being provided with an active element and a display element, the bending region being adjacent to the display region, the terminal region being outside the bending region, includes: forming the bending region by at least partially removing one or more layers of inorganic films formed in each of the display region, the bending region, and the terminal region; forming a first resin layer on the one or more layers of inorganic films in the display region and the terminal region, the first resin layer filling the bending region; forming a first opening in the first resin layer and the one or more layers of inorganic films in the display region, the first opening exposing an extension wiring line electrically connected with the active element; and forming a lead wiring line on the first resin layer in the bending region, the lead wiring line being electrically connected with the extension wiring line via the first opening.

With the above method, the first resin layer fills the bending region and is formed on the one or more layers of inorganic films in the display region and the terminal region. In addition, the lead wiring line is electrically connected with the extension wiring line via the first opening and is formed on the first resin layer in the bending region.

Thus, with the first resin layer, the display region and the terminal region can be leveled. In addition, disconnection of the lead wiring line can be suppressed in the bending region, and an increase in resistance due to the lead wiring line having an unnecessarily long length can be suppressed.

According to aspect 15 of the disclosure, in the method of manufacturing the flexible display device having the features of aspect 14, forming the first opening in the first resin layer and the one or more layers of inorganic films may include forming an opening in the one or more layers of inorganic films using an opening formed in the first resin layer and the first resin layer as a mask.

The above method can suppress a fault in formation of the first opening.

According to aspect 16 of the disclosure, in the method of manufacturing the flexible display device having the features of aspect 14, forming the first opening in the first resin layer and the one or more layers of inorganic films may include forming an opening in the one or more layers of inorganic films and then forming an opening in the first resin layer.

The above method enables the bending region and the opening in the one or more layers of inorganic film to be formed in a single step.

According to aspect 17 of the disclosure, in the method of manufacturing the flexible display device having the features of any one of aspects 14 to 16, the one or more layers of inorganic films formed on each of the display region, the bending region, and the terminal region may be formed on a second resin layer formed on one surface of a non-flexible substrate, and the method may further include peeling off the non-flexible substrate from the second resin layer by radiating a laser beam from a side having the non-flexible substrate; and bonding a flexible substrate to a surface of the second resin layer, the non-flexible substrate being peeled off from the surface of the second resin layer.

The above method can achieve a method of manufacturing a flexible display device including a Laser Lift Off step (also referred to as LLO step).

According to aspect 18 of the disclosure, in the method of manufacturing the flexible display device having the features of any one of aspects 14 to 17, the first resin layer may be formed from polyimide resin containing a photosensitive material.

The above method can achieve a flexible display device in which the first resin layer can be patterned in exposure and development steps, and moisture or impurities can be more effectively inhibited from permeating.

According to aspect 19 of the disclosure, in the method of manufacturing the flexible display device having the features of any one of aspects 14 to 17, the first resin layer may be formed from acrylic resin containing a photosensitive material.

The above method can achieve a flexible display device in which the first resin layer can be patterned in exposure and development steps and, in the case of the display element of a bottom emission type, a decrease in transmittance of emitted light due to the first resin layer is reduced.

According to aspect 20 of the disclosure, in the method of manufacturing the flexible display device having the features of any one of aspects 14 to 19, the bending region may include an opening region of the one or more layers of inorganic films.

The above method can achieve a flexible display device in which readiness of bending in the bending region is further improved and a crack or the like is prevented in the bending region.

According to aspect 21 of the disclosure, in the method of manufacturing the flexible display device having the features of aspect 17, the second resin layer may be formed from polyimide resin.

The above method can achieve a flexible display device in which moisture or impurities can be more effectively inhibited from permeating.

According to aspect 22 of the disclosure, in the method of manufacturing the flexible display device having the features of any one of aspects 14 to 21, the display element may include an organic EL display element.

The above method can achieve a flexible display device including an organic EL display element as the display element.

According to aspect 23 of the disclosure, in the method of manufacturing the flexible display device having the features of any one of aspects 14 to 21, the display element may include a reflective liquid crystal display element.

The above method can achieve a flexible display device including a reflective liquid crystal display element as the display element.

### Additional Items

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure is applicable to a flexible display device and a method of manufacturing a flexible display device.

### REFERENCE SIGNS LIST

1 Glass substrate (Non-flexible substrate)
2 PI layer (Second resin layer)
3 Moisture-proof layer (Inorganic film)
4 Semiconductor layer
5 Gate insulating layer (Inorganic film)
6a Gate electrode
6b Capacitance electrode
6c Gate electrode extension wiring line (Extension wiring line, Conductive member)
7 Second insulating layer (Inorganic film)
8 Capacitance counter electrode
9 Third insulating layer (Inorganic film)
10 Photosensitive PI layer (First resin layer)
10a Opening
11 Conductive layer
11a Drain wiring line
11b Gate wiring line
11c Capacitance wiring line
11d Lead wiring line
12 Photosensitive flattening layer (Third resin layer)
12a, 12b Opening
13 First electrode
14 Display element
15 Sealing film
19 Film substrate (Flexible substrate)
30 Flexible organic EL display device (Flexible display device)
AA Display region
NAA Non-display region
BA Bending region
TA Terminal region
CH Contact hole
BH Bending hole

1. A flexible display device comprising:
a flexible substrate; and
an active element and a display element disposed on the flexible substrate,
wherein the active element and the display element are disposed in a display region,
a bending region and a terminal region are disposed in a vicinity of the display region, the bending region being adjacent to the display region, the terminal region being outside the bending region,
one or more layers of inorganic films are disposed in each of the display region, the bending region, and the terminal region on the flexible substrate, and the one or more layers of inorganic films are at least partially removed in the bending region,
a first resin layer fills the bending region and is formed on the one or more layers of inorganic films in the display region and the terminal region,
a first opening is formed in the first resin layer and the one or more layers of inorganic films in the display region while exposing an extension wiring line electrically connected with the active element, and
a lead wiring line is electrically connected with the extension wiring line via the first opening and is formed on the first resin layer in the bending region.

2. The flexible display device according to claim 1,
wherein the first opening includes an opening formed in the first resin layer and an opening formed in the one or more layers of inorganic films, and
side surfaces of the opening formed in the first resin layer and side surfaces of the opening formed in the one or more layers of inorganic films are aligned with each other at portions of contact between the opening formed in the first resin layer and the opening formed in the one or more layers of inorganic films.

3. The flexible display device according to claim 1,
wherein a second opening is formed in the first resin layer and the one or more layers of inorganic films in the display region while exposing a semiconductor layer or a gate electrode of the active element, and a wiring line for the active element is electrically connected with the active element via the second opening.

4. The flexible display device according to claim 3,
wherein the second opening includes an opening formed in the first resin layer and an opening formed in the one or more layers of inorganic films, and
side surfaces of the opening formed in the first resin layer and side surfaces of the opening formed in the one or more layers of inorganic films are aligned with each other at portions of contact between the opening formed in the first resin layer and the opening formed in the one or more layers of inorganic films.

5. The flexible display device according to claim 1,
wherein a capacitance element is disposed in the display region, the capacitance element including a capacitance electrode and a capacitance counter electrode formed on a layer above the capacitance electrode via an insulating layer,
a third opening is formed in the first resin layer and the one or more layers of inorganic films in the display region while exposing the capacitance counter electrode, and
a wiring line for the capacitance element is electrically connected with the capacitance counter electrode via the third opening.

6. The flexible display device according to claim 5,
wherein the third opening includes an opening formed in the first resin layer and an opening formed in the one or more layers of inorganic films, and
side surfaces of the opening formed in the first resin layer and side surfaces of the opening formed in the one or more layers of inorganic films are aligned with each other at portions of contact between the opening formed in the first resin layer and the opening formed in the one or more layers of inorganic films.

7. The flexible display device according to claim 1,
wherein a fourth opening is formed in the first resin layer and the one or more layers of inorganic films in the terminal region while exposing a conductive member, and
the lead wiring line is electrically connected with the conductive member via the fourth opening.

8. The flexible display device according to claim 7,
wherein the fourth opening includes an opening formed in the first resin layer and an opening formed in the one or more layers of inorganic films, and
side surfaces of the opening formed in the first resin layer and side surfaces of the opening formed in the one or more layers of inorganic films are aligned with each other at portions of contact between the opening formed in the first resin layer and the opening formed in the one or more layers of inorganic films.

9. The flexible display device according to any claim 1,
wherein the bending region includes an opening region of the one or more layers of inorganic films.

10. The flexible display device according to claim 1,
wherein the first resin layer is formed from polyimide resin containing a photosensitive material.

11. The flexible display device according to claim 1,
wherein the first resin layer is formed from acrylic resin containing a photosensitive material.

12. The flexible display device according to claim 1,
wherein the display element includes an organic EL display element.

13. The flexible display device according to claims 1,
wherein the display element includes a reflective liquid crystal display element.

14. A method of manufacturing a flexible display device including a display region, a bending region, and a terminal region, the display region being provided with an active element and a display element, the bending region being adjacent to the display region, the terminal region being outside the bending region, the method comprising:
forming the bending region by at least partially removing one or more layers of inorganic films formed in each of the display region, the bending region, and the terminal region;
forming a first resin layer on the one or more layers of inorganic films in the display region and the terminal region, the first resin layer filling the bending region;
forming a first opening in the first resin layer and the one or more layers of inorganic films in the display region, the first opening exposing an extension wiring line electrically connected with the active element; and
forming a lead wiring line on the first resin layer in the bending region, the lead wiring line being electrically connected with the extension wiring line via the first opening.

15. The method of manufacturing the flexible display device, according to claim 14,
wherein forming the first opening in the first resin layer and the one or more layers of inorganic films includes forming an opening in the one or more layers of inorganic films, using an opening formed in the first resin layer and the first resin layer as a mask.

16. The method of manufacturing the flexible display device, according to claim 14,
wherein forming the first opening in the first resin layer and the one or more layers of inorganic films includes forming an opening in the one or more layers of inorganic films, and then forming an opening in the first resin layer.

17. The method of manufacturing the flexible display device, according to claim 14,
wherein the one or more layers of inorganic films formed on each of the display region, the bending region, and the terminal region are formed on a second resin layer formed on one surface of a non-flexible substrate, and
the method further includes peeling off the non-flexible substrate from the second resin layer by radiating a laser beam from a side having the non-flexible substrate, and
bonding a flexible substrate to a surface of the second resin layer, the non-flexible substrate being peeled off from the surface of the second resin layer.

18. The method of manufacturing the flexible display device, according to claim 14,
wherein the first resin layer is formed from polyimide resin containing a photosensitive material.

19. The method of manufacturing the flexible display device, according to claim 14,
wherein the first resin layer is formed from acrylic resin containing a photosensitive material.

20. The method of manufacturing the flexible display device, according to claim 14,
wherein the bending region includes an opening region of the one or more layers of inorganic films.

21-23. (canceled)
